(19) United States
(12) Patent Application Publication
(10) Pub. No.: US 2025/0072187 A1
(43) Pub. Date: Feb. 27, 2025

(54) OPTOELECTRONIC ARRAY AND METHOD FOR MANUFACTURING AN OPTOELECTRONIC ARRAY

(71) Applicant: ams-OSRAM International GmbH, Regensburg (DE)

(72) Inventor: Siegfried Herrmann, Neukirchen (DE)

(21) Appl. No.: 18/726,950

(22) PCT Filed: Jan. 13, 2022
(86) PCT No.: PCT/EP2022/050688

§ 371 Date: Jul. 5, 2024

(51) Int. Cl. H01L 33/62; H01L 25/075

(52) U.S. Cl. CPC H01L 33/62; H01L 25/0753; H01L 2933/0066

(57) ABSTRACT

In an embodiment an optoelectronic array includes a first structured layer with a plurality of first regions, the first structured layer including a semiconductor material of a first doping type, a second structured layer with a plurality of second regions arranged on the first structured layer, the second structured layer including a semiconductor material of a second doping type and a plurality of active regions arranged between respective first and second regions forming optoelectronic elements, wherein first regions along a row of the plurality of rows are connected by first contact bridges, wherein second regions along a column of the plurality of columns are connected by second contact bridges, wherein the first contact bridges comprise a semiconductor material of the first doping type, and wherein the second contact bridges comprise a semiconductor material of the second doping type.

### CROSS-REFERENCE TO RELATED APPLICATIONS

This patent application is a national phase filing under section 371 of PCT/EP2022/050688, filed Jan. 13, 2022, which is incorporated herein by reference in its entirety.

### TECHNICAL FIELD

The present invention concerns an optoelectronic array with a plurality of optoelectronic elements arranged in a plurality of rows and columns as well as a method for manufacturing an optoelectronic array with a plurality of optoelectronic elements arranged in a plurality of rows and columns.

### BACKGROUND

The recent decrease in size of optoelectronic elements such as LEDs has led to the development of μ-LEDs, whose size lies in the area or less than 1000 μm² and can go down to about 10 μm². However, with the miniaturization of the optoelectronic elements, one quickly reaches the limits of a connection concept for such small optoelectronic elements arranged in close proximity to each other.

A commonly known strategy to contact and control an array of optoelectronic elements, or a plurality of pixels comprising one or more optoelectronic elements, such as for example in a display, is to each connect the optoelectronic elements or pixels to a control module (ASIC, CMOS etc.) by separate contacts. Such contacts can for example be of the form of conductive tracks on a carrier substrate on which the optoelectronic elements are arranged and/or on the optoelectronic elements itself.

In particular in case of very small sized optoelectronic elements arranged in close proximity to each other, a contacting by use of conductive tracks arranged on the optoelectronic elements is very difficult due to the required high positioning accuracy and their small dimensions. In addition, with decreasing size of the optoelectronic elements, such a contacting is becoming more and more difficult to fabricate.

### SUMMARY

Embodiments provide an optoelectronic array with a plurality of optoelectronic elements arranged in a plurality of rows and columns with an improved contacting structure. Further embodiments provide a method for manufacturing a respective optoelectronic array.

Embodiments provide a compact optoelectronic array with a plurality of optoelectronic elements arranged in a plurality of rows and columns, also called LED matrix. Conductor tracks connecting the optoelectronic elements are thereby an integral part of the optoelectronic array and in particular an integral part of the base body of the optoelectronic elements. Namely, the conductor tracks connecting the optoelectronic elements, which are mainly called contact bridges in the following, may at least partially comprise the same epitaxial substrate as the epitaxial substrate the optoelectronic elements are grown of and thus form epitaxial ridges. The proposed concept is in particular suitable for an array of LEDs in the submicrometer range or for an array of pixelated chips with edge lengths in the 10 μm range, which themselves my consist of even smaller subpixels, and provides an optoelectronic array of highest packing density of single micro- or nano LEDs.

In one aspect, an optoelectronic array with a plurality of optoelectronic elements arranged in a plurality of rows and columns is provided, the optoelectronic array comprising a first structured layer with a plurality of first regions and a second structured layer with a plurality of second regions, the second structured layer being arranged on the first structured layer. The first structured layer thereby comprises a semiconductor material of a first doping type and the second structured layer comprises a semiconductor material of a second doping type. Between respective first and second regions, a plurality of active regions is arranged, forming with a first and respective second region the optoelectronic elements. In addition, first regions are connected by first contact bridges along a row of the plurality of rows and second regions are connected by second contact bridges along a column of the plurality of columns.

The optoelectronic array can in particular comprise a plurality of optoelectronic elements arranged in a plurality of rows and columns, wherein each optoelectronic element is formed by a first region, a second region and an active region between the fist and the second region. The optoelectronic elements are connected to each other by first and second contact bridges, wherein the first contact bridges connect first regions along the plurality of rows, and wherein the second contact bridges connect second regions along the plurality of columns. The optoelectronic elements are thus connected in form of a matrix circuit. For a matrix circuit, individual optoelectronic elements are arranged and electrically connected in columns and rows and, for example, all positive poles of the optoelectronic elements are connected row by row by first contact bridges, while all negative poles are connected column by column by second contact bridges (this is however exemplarily and all negative poles can as well be connected row by row, while all positive poles are connected column by column as well). As soon as a certain column and a certain row are connected to a supply voltage, current starts to flow through the optoelectronic element that is located at the intersection of the connected row and column. If several optoelectronic elements are to be switched on, the control can be carried out sufficiently fast one after the other or similarly.

To control the optoelectronic elements, each row and each column of the plurality of rows and columns can for example be coupled to a control module such as an ASIC, CMOS etc., to connect the rows and columns to a supply voltage in a desired manner.

The first doping type can for example be an n-doping of the first structured layer, while the second doping type can be a p-doping of the second structured layer. This shall however be exemplarily, and the first doping type can as well be a p-doping while the second doping type can be an n-doping.

In some aspects, the optoelectronic elements are formed as light emitting elements and in particular as light emitting diodes (LED). The light emitting diodes may emit light of a desired wavelength when connected to a respective supply voltage. In particular the light emitting diodes may generate the emitted light within the active region of each optoelectronic element and emit it through the first and second region as well as through the side surfaces of the active region. The optoelectronic elements of an optoelectronic array may for example emit light of the same wavelength, light of slightly different wavelengths, or light of different wavelengths. Light of different wavelengths may thereby originate from different material systems used for the optoelectronic elements, different bandgaps in the respective active region of the optoelectronic elements or due to a light converter material arranged on at least some of the optoelectronic elements.

In some aspects, the first contact bridges remain free of the semiconductor material of the second doping type. In some aspects the second contact bridges remain free of the semiconductor material of the first doping type. The first contact bridges may thus contact first regions, but may not contact second regions and may also not contact second contact bridges. Further to this, second contact bridges may contact second regions, but may not contact first regions and also not first contact bridges. This is in particular to avoid a short in the optoelectronic array and to ensure a proper functionality of the optoelectronic array.

In areas of the first and second contact bridges no active regions may be present on either the first or the second regions respectively. The contact bridges can thus form conductive but non-emissive areas of the optoelectronic array, while the optoelectronic elements can form light emissive areas of the optoelectronic array.

In some aspects, the first contact bridges comprise a semiconductor material of the first doping type, in particular the same semiconductor material of the same doping type as the first structured layer. The first contact bridges may for example be grown during the same step as the first structured layer and can thus form an integral part of the first structured layer.

In some aspects, the second contact bridges comprise a semiconductor material of the second doping type, in particular the same semiconductor material of the same doping type as the second structured layer. The second contact bridges may for example be grown during the same step as the second structured layer and can thus form an integral part of the second structured layer.

In some aspects, the first contact bridges comprise a higher doping concentration of the first doping type than the first regions. The first contact bridges may therefore comprise a higher electrical conductivity than the first regions. This can in particular be advantageous, as the first contact bridges act as conductor tracks in-between first regions or in particular in-between optoelectronic elements and thus should have a high electrical conductivity.

In some aspects, the second contact bridges comprise a higher doping concentration of the second doping type than the second regions. The second contact bridges may therefore comprise a higher electrical conductivity than the second regions. This can in particular be advantageous, as the second contact bridges act as conductor tracks in-between second regions or in particular in-between optoelectronic elements and thus should have a high electrical conductivity.

In some aspects, the optoelectronic array further comprises a plurality of first contacts each coupled to a first region of the rows of the optoelectronic elements. In particular, each row of first regions being connected to each other can be coupled to a first contact. The first contacts may thereby be coupled to an outer optoelectronic element of each row of the optoelectronic array, with the outer optoelectronic elements of each row together forming an outer column of the optoelectronic array. However, the first contacts may also contact any other optoelectronic element of the rows of the optoelectronic array.

In some aspects, the plurality of first contacts each comprise a contact via through the second structured layer. The contact vias may thereby each be electrically isolated from the second structured layer by use of an electrically isolating material arranged between the contact vias and the second structured layer to avoid a short. An electrical connection of the optoelectronic array can therefore be provided from the same side of the optoelectronic array, namely the side of the second structured layer.

In some aspects, the optoelectronic array further comprises a plurality of second contacts each coupled to a second region of the columns of the optoelectronic elements. In particular, each column of second regions being connected to each other can be coupled to a second contact. The second contacts may thereby be coupled to an outer optoelectronic element of each column of the optoelectronic array, with the outer optoelectronic elements of each column together forming an outer row of the optoelectronic array. However, the second contacts may also contact any other optoelectronic element of the columns of the optoelectronic array.

In some aspects, the plurality of second contacts each comprise a contact pad arranged on a respective second region. The contact pads may thereby each be electrically coupled to the respective second region. An electrical connection of the optoelectronic array can in connection with the contact vias therefore be provided from the same side of the optoelectronic array, namely the side of the second structured layer.

In some aspects, the first regions each jacket respective second regions at least partly. Respective first and second regions may be arranged on top of each other in a way, such that the first region at least partly embeds the second region or vice versa. The second regions can for example be of the form of a cone whereas the first regions can be of the form of a hollow cone arranged above the cone and at least partly jacketing the second regions. The geometric specification of the form of a cone and a hollow cone shall however not be understood as limiting. The first and second regions can also be of the form of a pyramid and a hollow pyramid, a cylinder and a hollow cylinder, a sphere and a hollow hemisphere, or the like. The active region is thereby arranged between respective first and second regions and must not be formed of a planar plane between first and respective second regions but may be formed along the whole contacting surface between respective first and second regions.

In some aspects, the first contact bridges and/or the second contact bridges comprise nanorods. The dimensions of single nanorods can range from 1-100 nm and the nanorods may be long compared to their width. They may be synthesized from metals or semiconducting materials. In case of the present application a plurality of such nanorods can for example form the first and/or second contact bridges.

In some aspects, the first contact bridges and/or the second contact bridges comprise an electrically conductive material different from the semiconductor material of the first and second doping type respectively. The first contact bridges and/or the second contact bridges may therefore not form an integral part with the first and second structured layer but may electrically connect first and second regions in form of for example metallic conductor tracks in above described manner.

In some aspects, the optoelectronic array further comprises an electrically insulating material, such as for example a ceramic or a plastic, arranged in trough holes between the optoelectronic elements. Besides the contact bridges, the optoelectronic elements may be separated from each other by through holes, which may for example be filled by an electrically insulating material. This electrically insulating material can for example serve as an electrical isolation between the optoelectronic elements and between first and second contact bridges, can for example serve as a mechanical stabilizer of the optoelectronic array, and/or can for example serve as a reflective and/or light absorbing medium between the optoelectronic elements, in particular surrounding the optoelectronic elements. A light emitted trough a side surface of an optoelectronic element may therefore be reflected or absorbed by the electrically insulating material to provide that the optoelectronic array emits light only through its top and/or bottom surface side. In addition, or as an alternative, either on the first structured layer or on the second structured layer a reflective layer may be arranged, to provide that the optoelectronic array emits light only through one surface side, namely its top or bottom surface side. In addition, or as an alternative, the optoelectronic elements may be at least partially jacketed by a reflective layer to improve a light emitting efficiency of the optoelectronic array.

In some aspects, the first contact bridges comprise a thickness which is smaller than a thickness of the first structured layer, and/or the second contact bridges comprise a thickness which is smaller than a thickness of the second structured layer. In some aspects, the first contact bridges comprise however an at least approximately equal thickness as a thickness of the first structured layer, and the second contact bridges comprise an at least approximately equal thickness as a thickness of the second structured layer. By the term thickness, it is particularly meant the dimension of the contact bridges along the growing direction of the optoelectronic elements.

In some aspects, the first contact bridges comprise a width which is smaller than a width of a first region being in contact with a respective contact bridge and/or the second contact bridges comprise a width which is smaller than a width of a second region being in contact with a respective contact bridge. By the term width, it is particularly meant the dimension of the contact bridges in a direction perpendicular to the growing direction of the optoelectronic elements and along a side surface of the optoelectronic elements being in contact with a respective contact bridge. The contact bridges can however also comprise an at least approximately equal width as the respective first and second regions.

In some aspects, respective first and second regions are arranged above each other at least approximately congruently. Respective first and second regions may therefore comprise an equal cross section arranged above each other. The first and second regions may each for example comprise one of a rectangular, round, oval, trapezoidal, polygonal, or any other cross section.

It is also proposed an optoelectronic device comprising an integrated circuit, or a circuit board, on which at least one optoelectronic array according to any one of the aforementioned aspects is arranged. On the integrated circuit also several of the optoelectronic arrays may be arranged in for example rows and columns forming a display. The optoelectronic arrays, and in particular the rows and columns of the optoelectronic arrays may thereby be connected to the integrated circuit and controlled by the same.

It is also proposed a method for manufacturing an optoelectronic array with a plurality of optoelectronic elements arranged in a plurality of rows and columns, the method comprising the steps:
Providing a layer stack of a first layer and a second layer, the first layer comprising a semiconductor material of a first doping type, and the second layer comprising a semiconductor material of a second doping type;
Etching first openings into the second layer, wherein the first openings are arranged between optoelectronic elements along the plurality of rows;
Etching second openings into the first layer, wherein the second openings are arranged between optoelectronic elements along the columns; and
Etching through holes through the layer stack, the through holes and the second openings structuring the first layer into a plurality of first regions and a plurality of first contact bridges and the through holes and the first openings structuring the second layer into a plurality of second regions and a plurality of second contact bridges.

First regions are thereby connected along rows of the plurality of rows by the first contact bridges and second regions are connected along columns of the plurality of columns by the second contact bridges. Further to this, each a first and a respective second region with an active region arranged in-between forms an optoelectronic element.

In some aspects, the layer stack is provided on a first carrier substrate, the first layer facing the first carrier substrate. In particular, the step of providing a layer stack may comprise an epitaxial growing of the layer stack on a first carrier substrate, wherein the first carrier substrate may for example be a wafer.

In some aspects, the step of etching the through holes is performed after the step of etching the first and the second openings. In particular the step of etching the first and second openings, as well as the through holes serves to divide the layer stack into the plurality of optoelectronic elements, each comprising of a first region, a respective second region, and an active region between the first and second region, as well as into the first and second contact bridges connecting first and second regions respectively. The first openings are thereby etched into the second layer in areas, where later first contact bridges are generated in the first layer, whereas the second openings are etched into the first layer in areas, where later second contact bridges are generated in the second layer. The first openings are thereby etched into the second layer with such a depth that the second layer is removed completely in these areas, whereas the second openings are etched into the first layer with such a depth that the first layer is removed completely in these areas. In combination with the trough holes through the layer stack, the plurality of optoelectronic elements, as well as the first and second contact bridges are generated.

In some aspects, the method further comprises a step of providing at least one second contact on an edge region of the second layer. In particular the at least one second contact can be provided on an edge region of the second layer such that it is arranged on an outer optoelectronic element of a column of the optoelectronic array.

In some aspects, the method further comprises a step of providing a release layer on the second layer and the optional at least one second contact, the release layer serving as a layer which may in the further processing of the optoelectronic array at least partially be removed.

In some aspects, the method further comprises a step of providing a second carrier substrate on the release layer. The second carrier substrate may thereby serve to provide a structure with which the layer stack can be held to process the side of the layer stack opposing the second carrier substrate. The step of providing the second carrier substrate can thus be followed by a step of turning the layer stack by at least approximately 180°.

To further process the first layer of the layer stack, the first carrier substrate can be removed from the same, for example after the second carrier substrate has been provided and the layer stack has been turned. The second openings can for example be etched into the first layer after the second carrier substrate has been provided, the layer stack has been turned and the first carrier substrate has been removed.

In some aspects, the method further comprises a step of providing at least one first contact in an edge region of the first layer. In particular the at least one first contact can be provided in an edge region of the first layer such that it is arranged in the vicinity or on an outer optoelectronic element of a row of the optoelectronic array.

In some aspects, the method further comprises a step of filling the through holes and/or the first and/or the second openings with an electrically insulating material, such as for example a ceramic or a plastic material. Besides the contact bridges, the optoelectronic elements may be separated from each other by the through holes, which may be filled with the electrically insulating material. This electrically insulating material can for example serve as an electrical isolation between the optoelectronic elements and between first and second contact bridges, can for example serve as a mechanical stabilizer of the optoelectronic array, and/or can for example serve as a reflective and/or light absorbing medium between the optoelectronic elements, in particular surrounding the optoelectronic elements.

In some aspects, the method further comprises an at least partial removal of the release layer. In particular, the release layer between the second layer and the second carrier substrate is removed such that only one or a plurality of pillars of the release layer remains between the second layer and the second carrier substrate. By this, the optoelectronic array can easily be removed from the second carrier substrate for example.

In some aspects, the method further comprises a lift off process of the optoelectronic array from the second carrier substrate and an optionally remaining release layer. The optionally remaining release layer can thereby be of the form of one or more pillars between the second layer and the second carrier substrate, from which the optoelectronic array can be torn off from.

### BRIEF DESCRIPTION OF THE DRAWINGS

In the following, embodiments of the invention will be explained in more detail with reference to the accompanying drawings.

FIGS. 1A and 1B show an optoelectronic array as well as a detailed view of the optoelectronic array according to some aspects of the invention;

FIG. 2 shows a detailed view of an embodiment of first and second contact bridges of an optoelectronic array according to some aspects of the invention;

FIG. 3 shows an isometric view of a further embodiment of an optoelectronic array according to some aspects of the invention;

FIG. 4 shows an isometric view of a further embodiment of an optoelectronic array with first and second contact elements according to some aspects of the invention;

FIGS. 5A and 5B show a side view of further embodiments of an optoelectronic array with first and second contact elements according to some aspects of the invention;

FIG. 6 shows an optoelectronic device with a plurality of optoelectronic arrays according to some aspects of the invention; and

FIG. 7A to 7J show steps of a method for manufacturing an optoelectronic array according to some aspects of the invention.

### DETAILED DESCRIPTION OF ILLUSTRATIVE EMBODIMENTS

The present disclosure will now be described more fully hereinafter with reference to the accompanying drawings, in which exemplary embodiments of the disclosure are shown. The disclosure may, however, be embodied in many different forms and should not be construed as limited to the embodiments set forth herein; rather, these embodiments are provided for thoroughness and completeness. Like reference characters refer to like elements throughout the description. The drawings are not necessarily to scale and certain features may be exaggerated in order to better illustrate and explain the exemplary embodiments of the present disclosure.

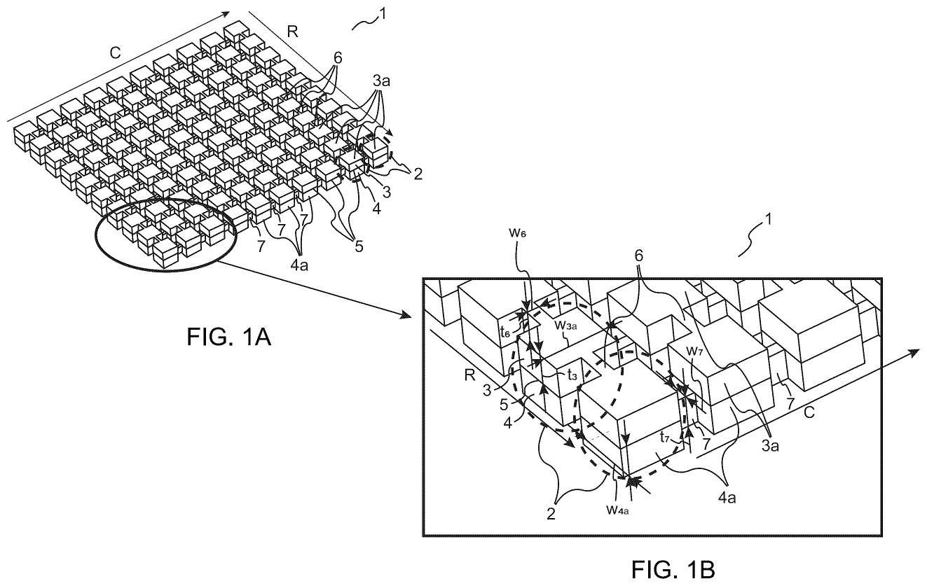

FIG. 1A shows an optoelectronic array 1 with a plurality of optoelectronic elements 2 arranged in a plurality of rows R and columns C. The optoelectronic array 1 comprises a first structured layer 3 with a plurality of first regions 3a, and a second structured layer 4 with a plurality of second regions 4a arranged on the first structured layer 3a. The first structured layer 3 comprises a semiconductor material of a first doping type and the second structured layer 4 comprises a semiconductor material of a second doping type. Between respective first 3a and second regions 4a, each an active region 5 of a plurality of active regions 5 is arranged, each a first region 3a, a second region 4a and an active region 5 forming an optoelectronic element 2.

The optoelectronic elements 2 are electrically connected by first and second contact bridges 6, 7, in such a way that first regions 3a are connected along the rows R by first contact bridges 6 and second regions 4a are connected along the columns C by second contact bridges 7. The first regions 3a are however separated from each other along the columns C and the second regions are separated from each other along the rows R. The optoelectronic elements 2 are thus connected in form of a matrix circuit.

In a matrix circuit, individual optoelectronic elements 2 are arranged and electrically connected in columns and rows and for example all positive poles of the optoelectronic elements 2 are connected row by row by first contact bridges 6, while all negative poles are connected column by column by second contact bridges 7. As soon as a certain column and a certain row are connected to a supply voltage, current starts to flow through the optoelectronic element 2 that is located at the intersection of the connected row and column.

As shown in the detail view in FIG. 1B, the first contact bridges 6 do not intersect with the second contact bridges 7 and are also not in contact with them. In areas of the first contact bridges 6, the second structured layer 4 is removed and in areas of the second contact bridges 7 the first structured layer 3 is removed.

In addition, it is shown in FIG. 1B that the first contact bridges 6 comprise an at least approximately equal thickness t₆ as the thickness t₃ of the first structured layer 3/a first region 3a being in contact with the respective contact bridge, and that the second contact bridges 7 comprise an at least approximately equal thickness t_{y} as the thickness t₄ of the second structured layer 4/a second region 4a being in contact with the respective contact bridge. The width w₆ of the first contact bridges 6 and the width w₇ of the second contact bridges 7 is however smaller than the width w₃ₐ, w₄ₐ of a first or second region 3a, 4a being in contact with the respective contact bridge. In the shown embodiment, the first and second regions 3a, 4a each have a rectangular form/are cuboid and are arranged congruently on top of each other so that the optoelectronic elements 2 are basically cubic. However, any other form or shape of the first and second regions 3a, 4a as well as the optoelectronic elements 2 is possible too.

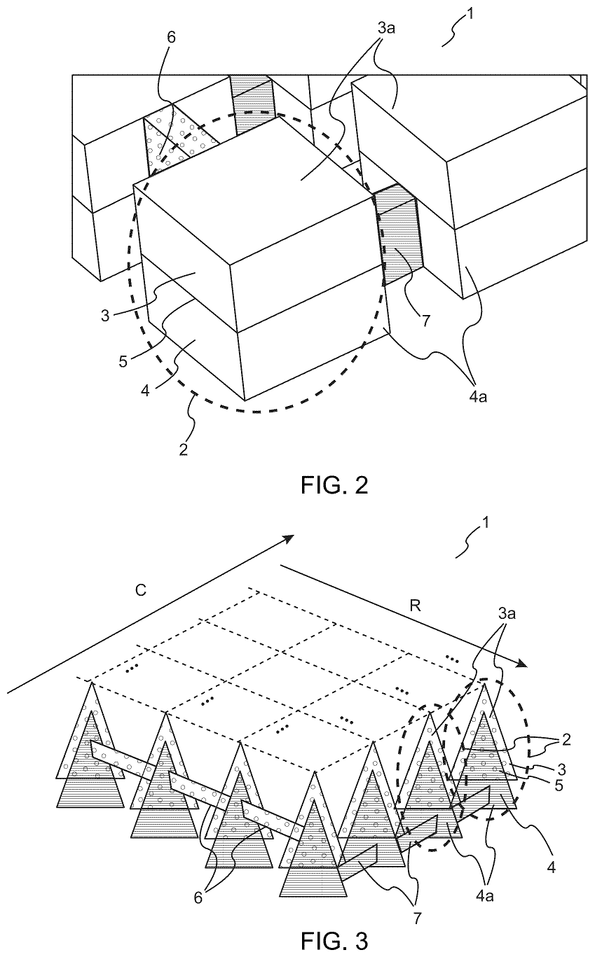

FIG. 2 shows a detailed view of an embodiment of first and second contact bridges 6, 7 of an optoelectronic array 1. Compared to the embodiment shown in FIGS. 1A and 1B, the first bridges 6 comprise a higher doping concentration of the first doping type and the second contact bridges 7 comprise a higher doping concentration of the second doping type. This is indicated by the dotted filling of the contact bridges. The higher doping concentration thereby serves to increase the electrical conductivity of the contact bridges, as the contact bridges act as conductive tracks between the optoelectronic elements.

FIG. 3 shows an isometric view of a further embodiment of an optoelectronic array 1. The first and second regions 3a, 4a are however not cuboid, but the second regions 4a are of the form of a cone and the first regions 3a are of the form of a hollow cone. Respective first and second regions 3a, 4a are arranged on top of each other in a way, such that a first region 3a partly jackets a second region 4a. The active region 5 is arranged between a respective first and second region and thus extends along the interface between the first and second region which corresponds basically to the lateral surface of a cone.

In the embodiment shown, only an outer column C and an outer row R of the optoelectronic array is drawn, but by the dotted lines and the ellipsis (dot-dot-dot) a continuation of the array is indicated.

The first contact bridges 6 and the second contact bridges 7 comprises besides a smaller width also a smaller thickness than the respective first/second regions being in contact with the contact bridges. The contact bridges can for example comprise nanorods which are grown between respective first/second regions forming the contact bridges.

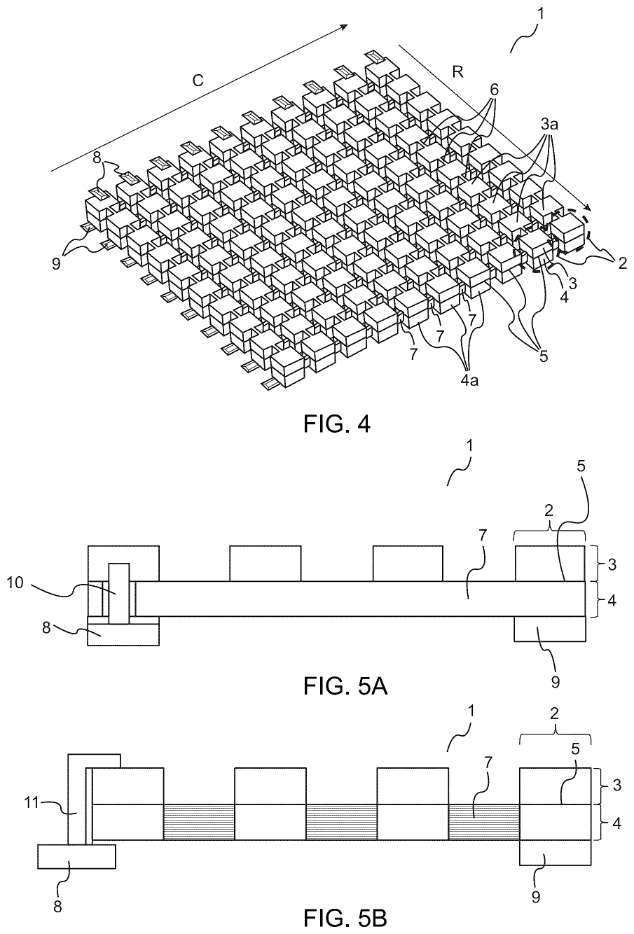

FIG. 4 shows an isometric view of a further embodiment of an optoelectronic array 1. In addition to the optoelectronic array 1 of FIG. 1A, each first contact 8 is coupled to a first region 3a of each row R of the optoelectronic array 1 and each second contact 9 is coupled to a second region 4a of each column of the optoelectronic array 1. In particular the first contacts 8 are each coupled to an outer optoelectronic element 2 of each row of the optoelectronic array 1, and thus to the optoelectronic elements 2 of an outer column of the optoelectronic array. The second contacts 9 are each coupled to an outer optoelectronic element 2 of each column of the optoelectronic array 1, and thus to the optoelectronic elements 2 of an outer row of the optoelectronic array. Through these contacts the optoelectronic elements 2 can be controlled in form of a matrix circuit.

FIGS. 5A and 5B each show a side view of further embodiments of an optoelectronic array 1 and in particular embodiments of the first and second contact elements 8, 9. According to FIG. 5A, the first contact 8 comprises a contact via 10 through the second structured layer 4 contacting the first structured layer 3/a respective first region 3a. The contact via 10 is electrically isolated from the second structured layer 4 by use of an electrically isolating material arranged between the contact via 10 and the second structured layer 4 to avoid a short. The second contact 9 comprises a contact pad arranged on the second structured layer/a respective second region 4a. The contact pad is electrically coupled to the respective second region 4a. An electrical connection of the optoelectronic array 1 can therefore be provided from the same side of the optoelectronic array, namely the side of the second structured layer 4.

FIG. 5B in contrast shows the first contact 8 without a contact via but with a conductive track 11 extending from a top surface of an optoelectronic element 2 along a side surface of the optoelectronic element 2 onto a bottom surface of the optoelectronic element 2. With the shown contact 8 an electrical connection of the optoelectronic array 1 can again be provided from the same side of the optoelectronic array, namely the side of the second structured layer 4.

In addition, and as an exemplary alternative FIG. 5B shows that the second contact bridges 7 comprise a higher doping concentration of the second doping type. This is indicated by the dotted filling of the contact bridges. The higher doping concentration thereby serves to increase the electrical conductivity of the contact bridges, as the contact bridges act as conductive tracks between the optoelectronic elements. It is to be understood, that the first contact bridges (not shown in this viewing angle) may also comprise a higher doping concentration, but may also not.

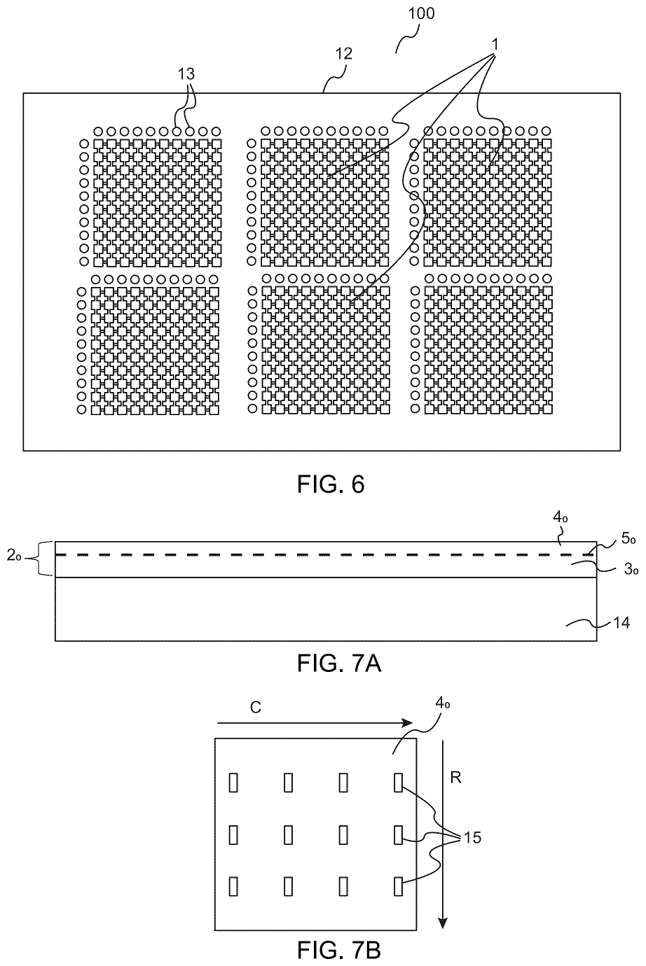

FIG. 6 shows an optoelectronic device 100 with a plurality of optoelectronic arrays 1 arranged on a circuit board 12 in rows and columns. The optoelectronic device 100 may for example form a display. The optoelectronic arrays 1, and in particular the rows and columns of the optoelectronic arrays 1 are connected to contact pads 13 on the circuit board 12 so that they can be controlled by the same.

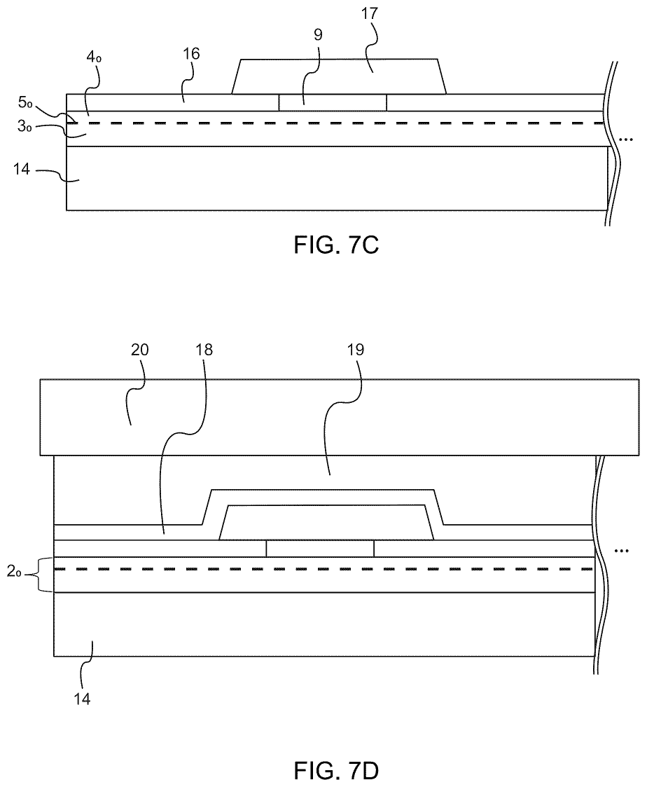

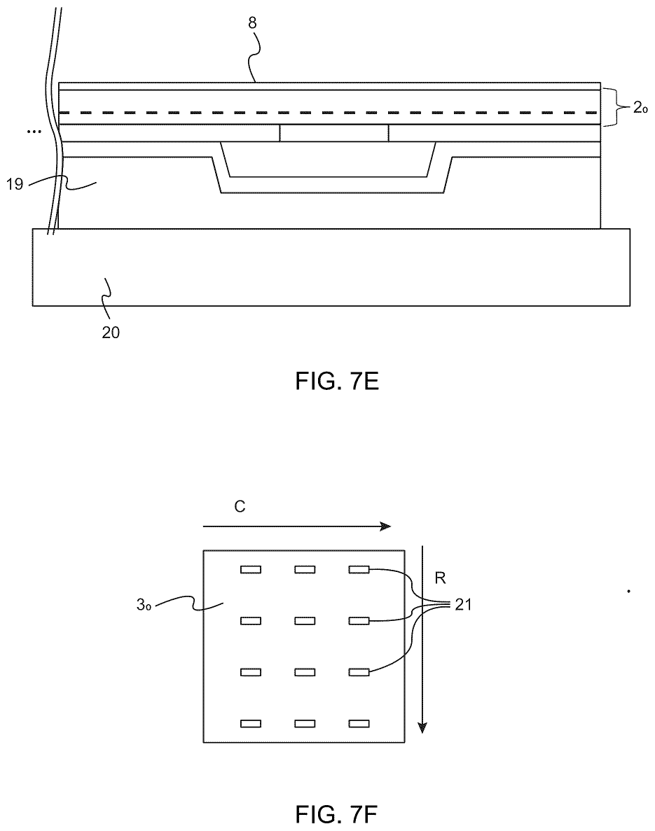

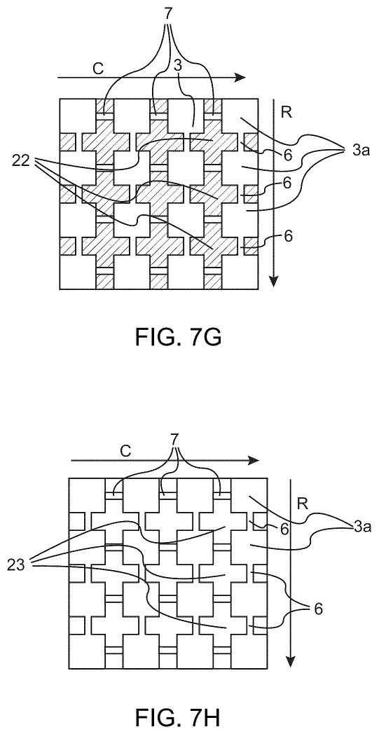

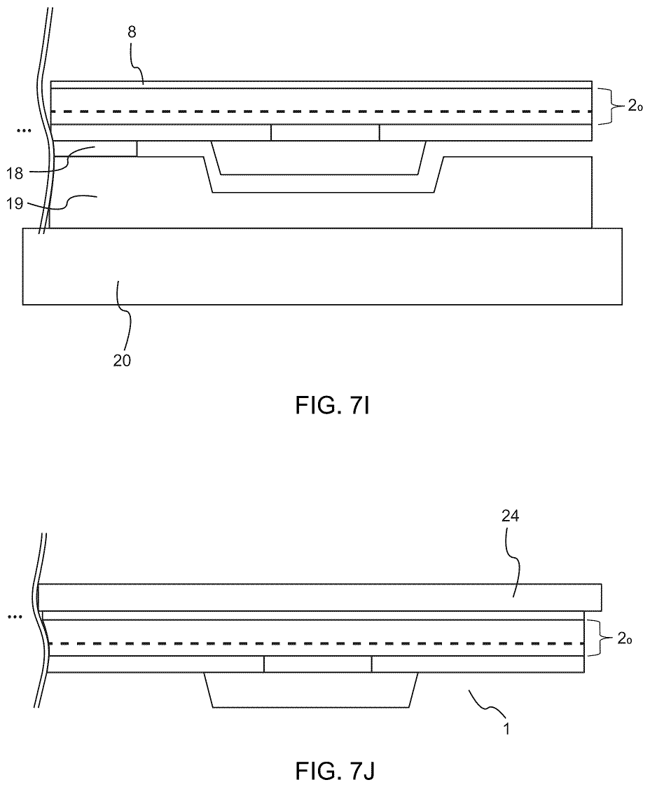

FIG. 7A to 7J show steps of a method for manufacturing an optoelectronic array 1 with a plurality of optoelectronic elements arranged in a plurality of rows and columns.

In a first step according to FIG. 7A, a layer stack 20 of a continuous first layer 3ₒ, a continuous second layer 4ₒ, and a continuous active region 5ₒ between the first layer 3ₒ and the second layer 4ₒ is provided on a first carrier substrate 14, the first layer 3ₒ facing the first carrier substrate 14. The first layer 3ₒ comprises a semiconductor material of a first doping type, and the second layer 4ₒ comprises a semiconductor material of a second doping type. The step of providing the layer stack 20 comprises an epitaxial growing of the layer stack on the first carrier substrate 14, wherein the first carrier substrate is for example a wafer.

In a further step according to FIG. 7B, first openings 15 are etched into the second layer 4ₒ. The first openings 15 are thereby arranged between later separated optoelectronic elements along the rows of the manufactured optoelectronic array. The first openings 15 are in particular etched into the second layer 4ₒ in areas, where later first contact bridges are generated in the first layer 3ₒ. Therefore, the first openings 15 are etched into the second layer 4ₒ with such a depth that the second layer 4ₒ is removed completely in these areas.

FIG. 7C shows only an edge region of the layer stack, in particular the edge region corresponding to one later formed optoelectronic element. The continuation of the layer stack 20 and the respective further layers and components is indicated by the waved lines.

In the step shown, a second contact 9 is provided on an edge region of the second layer 4ₒ. In particular the second contact 9 is provided on an edge region of the second layer 4ₒ such that it is arranged on a later formed outer optoelectronic element of a column of the optoelectronic array. In addition, an electrically isolating/protection layer 16, for example silicon dioxide, is arranged on the second layer 4ₒ to protect the layer stack from external influences as well as from an undesired short within the later optoelectronic array. The electrically isolating/protection layer 16 can also comprise reflective/light absorbing properties to guide light emitted from the later optoelectronic array but is an optional layer.

After this, a contact pad 17 is provided on top of the second contact 9, to contact the later optoelectronic array and to connect it to an external supply voltage. The contact pad 17 can for example comprise a metal layer and can for example form an integral part with the second contact 9.

According to FIG. 7D in a further step, a release layer 18 is provided on the electrically isolating/protection layer 16 contact pad 17. As the electrically isolating/protection layer 16 is an optional layer and as the contact pad 17 can form an integral part with the second contact 9 the release layer 18 can also be provided directly on the second layer 4ₒ and the second contact 9. The release layer serves at least partially as a sacrificial layer which in the further processing of the optoelectronic array is at least partially again removed. On the release layer 18 a holding structure comprising a second carrier substrate 20 and an intermediate layer 19 is provided in a subsequent step. The second carrier substrate 20 serves to provide a structure with which the layer stack 20 can be held to process the side of the layer stack opposing the second carrier substrate 20.

As shown in FIG. 7E the step of providing the second carrier substrate 20 is followed by a step of turning the layer stack by 180°. The first carrier substrate 14 is then removed and a first contact 8 in form of a transparent contact layer of for example indium tin oxide is provided on the layer stack 2ₒ, and in particular on the first layer 3ₒ.

After this, as shown in FIG. 7F, second openings 21 are etched into the first layer 3ₒ and the transparent contact layer. The second openings 21 are thereby arranged between later separated optoelectronic elements along the columns of the manufactured optoelectronic array. The second openings 15 are in particular etched into the first layer 3ₒ in areas, where later second contact bridges are generated in the second layer 4ₒ. Therefore, the second openings 21 are etched into the first layer 3ₒ with such a depth that the first layer 3ₒ is removed completely in these areas.

In a further step according to FIG. 7G, through holes 22 are etched through the layer stack 20 until the release layer 18. The through holes 22 are indicated by the hatching to show that the hatched area is to be removed. Depending on the desired form of the optoelectronic elements and the contact bridges with regard to shape size and size ratio to each other the through holes can however comprise a different size and or shape. The through holes 22 and the second openings 21 structure the first layer into a plurality of first regions 3a and a plurality of first contact bridges 7, while the through holes 8 and the first openings 15 structure the second layer into a plurality of second regions 4a and a plurality of second contact bridges 7. With the step of etching the first and second openings 15, 21 in combination with the step of etching the trough holes 22 through the layer stack 20, the plurality of optoelectronic elements 2, as well as the first and second contact bridges 6,7 are generated.

FIG. 7H shows a further step according to which the through holes 22 and the first and the second openings 15, 21 are filled with an electrically insulating material 23, such as for example a ceramic or a plastic material. The electrically insulating material can for example serve as an electrical isolation between the optoelectronic elements 2 and between first and second contact bridges 6,7, can for example serve as a mechanical stabilizer of the optoelectronic array, and can for example serve as a reflective or light absorbing medium between the optoelectronic elements 2, in particular surrounding the optoelectronic elements 2.

In a subsequent step, as shown in FIG. 7I, the release layer 18 is partially removed. In particular, the release layer 18 is removed such that only a pillar of the release layer 18 remains between the second structured layer 3 and the intermediate layer 19. By this, the optoelectronic array 1 can easily be removed from the holding structure for example.

FIG. 7J shows a last step of a lift off process of the optoelectronic array 1 from the holding structure and the remaining release layer pillar. The release layer pillar can thereby hold the optoelectronic array 1 in place ad act as a breaking point from which the optoelectronic array 1 can be torn off from when picked up by a Stamp 24.

1.-33. (canceled)

34. An optoelectronic array with a plurality of optoelectronic elements arranged in a plurality of rows and columns, the array comprising:
a first structured layer with a plurality of first regions, the first structured layer comprising a semiconductor material of a first doping type;
a second structured layer with a plurality of second regions arranged on the first structured layer, the second structured layer comprising a semiconductor material of a second doping type; and
a plurality of active regions arranged between respective first and second regions forming the optoelectronic elements,
wherein first regions along a row of the plurality of rows are connected by first contact bridges,
wherein second regions along a column of the plurality of columns are connected by second contact bridges,
wherein the first contact bridges comprise a semiconductor material of the first doping type, and
wherein the second contact bridges comprise a semiconductor material of the second doping type.

35. The optoelectronic array according to claim 34, wherein the first contact bridges comprise a higher doping concentration of the first doping type than the first regions.

36. The optoelectronic array according to claim 34, wherein the second contact bridges comprise a higher doping concentration of the second doping type than the second regions.

37. The optoelectronic array according to claim 34, further comprising a plurality of first contacts, each contact coupled to a first region of an optoelectronic element of an outer row of the optoelectronic array.

38. The optoelectronic array according to claim 37, wherein each of the plurality of first contacts comprises a contact via through the second structured layer.

39. The optoelectronic array according to claim 34, further comprising a plurality of second contacts, each contact coupled to a second region of an optoelectronic element of an outer column of the optoelectronic array.

40. The optoelectronic array according to claim 39, wherein each of the plurality of second contacts comprises a contact pad arranged on the second structured layer.

41. The optoelectronic array according to claim 34, wherein each first region jackets respective second regions at least partly.

42. The optoelectronic array according to claim 34, wherein the first contact bridges and/or the second contact bridges comprise nanorods.

43. The optoelectronic array according to claim 34, further comprising an electrically insulating material arranged in trough holes between the optoelectronic elements.

44. The optoelectronic array according to claim 34, wherein the first contact bridges remain free of the semiconductor material of the second doping type.

45. The optoelectronic array according to claim 34, wherein the second contact bridges remain free of the semiconductor material of the first doping type.

46. The optoelectronic array according to claim 34, wherein the first contact bridges comprise a thickness which is smaller than a thickness of the first structured layer, and wherein the second contact bridges comprise a thickness which is smaller than a thickness of the second structured layer.

47. The optoelectronic array according to claim 34, wherein the first contact bridges comprise an at least approximately equal thickness as a thickness of the first structured layer, and wherein the second contact bridges comprise an at least approximately equal thickness as a thickness of the second structured layer.

48. The optoelectronic array according to claim 34, wherein the first contact bridges comprise a width which is smaller than a width of a first region being in contact with the respective first contact bridge.

49. The optoelectronic array according to claim 34, wherein the second contact bridges comprise a width which is smaller than a width of a second region being in contact with the respective second contact bridge.

50. The optoelectronic array according to claim 34, wherein respective first and second regions are arranged above each other at least approximately congruently.

51. The optoelectronic array according to claim 34, wherein each of the first and second regions comprises one of a rectangular, round, oval, trapezoidal, or polygonal cross section.

52. A method for manufacturing an optoelectronic array with a plurality of optoelectronic elements arranged in a plurality of rows and columns, the method comprising:
providing a layer stack of a first layer and a second layer, the first layer comprising a semiconductor material of a first doping type and the second layer comprising a semiconductor material of a second doping type;
etching first openings into the second layer, wherein the first openings are formed between optoelectronic elements along the columns;
etching second openings into the first layer, wherein the second openings are formed between optoelectronic elements along the rows; and
etching through holes through the layer stack, wherein the through holes and the second openings structure the first layer into a plurality of first regions and a plurality of first contact bridges,
wherein the through holes and the first openings structure the second layer into a plurality of second regions and a plurality of second contact bridges,
wherein first regions along a row of the plurality of rows are connected by the first contact bridges,
wherein second regions along a column of the plurality of columns are connected by the second contact bridges, and
wherein each of a first region and a respective second region with an active region arranged therebetween forms an optoelectronic element.

53. The method according to claim 52, wherein the layer stack is provided on a first carrier substrate, the first layer facing the first carrier substrate.

54. The method according to claim 52, further comprising providing at least one second contact on an edge region of the second layer.

55. The method according to claim 52, further comprising providing a release layer on the second layer.

56. The method according to claim 55, further comprising providing a second carrier substrate on the release layer.

57. The method according to claim 53, further comprising removing the first carrier substrate.

58. The method according to claim 52, further comprising providing at least one first contact on at least an edge region of the first layer.

59. The method according to claim 57, wherein etching the second openings is performed after removing the first carrier substrate.

60. The method according to claim 52, wherein etching the through holes is performed after etching the second openings.

61. The method according to claim 52, further comprising filling the through holes and/or the first and/or the second openings with an electrically insulating material.

62. The method according to claim 55, further comprising at least partially removing the release layer.

63. The method according to claim 56, further comprising a lifting off the optoelectronic array from the second carrier substrate and an optionally remaining release layer.
